(19) United States
(12) Patent Application Publication
(10) Pub. No.: US 2018/0179631 A1
(43) Pub. Date: Jun. 28, 2018

(54) CONVEYOR DEVICE FOR A SUBSTRATE

(71) Applicant: AIXTRON SE, Herzogenrath (DE)

(72) Inventors: Nalin Lalith RUPESINGHE, Cambridge (GB); Gonçalo Pedro GONÇALVES, Cambridge (GB); Kenneth B.K. TEO, Cambridge (GB)

(21) Appl. No.: 15/739,108

(22) PCT Filed: Jun. 20, 2016
(86) PCT No.: PCT/EP2016/064117

§ 371 Date: Dec. 21, 2017

(30) Foreign Application Priority Data
Jun. 23, 2015 (DE) 10 2015 110 087.8

(51) Int. Cl. C23C 16/54; C23C 16/26; C23C 16/458

(52) U.S. Cl. CPC C23C 16/545; B82B 3/0004; C23C 16/4583; C23C 16/26

(57) ABSTRACT

A device for transporting a strip-type substrate through a reactor includes transport elements for holding the substrate. The transport elements are displaceable by a drive unit in a transport direction. The transport elements have first transport beams and second transport beams that engage in alternation on the substrate, in which the transport beams that engage the substrate move in the transport direction and the transport beams that do not engage the substrate move in a reverse direction opposite to the transport direction. The device further includes transport carriages that are arranged in pairs in the transport direction respectively upstream and downstream of the reactor.

### RELATED APPLICATIONS

This application is a National Stage under 35 USC 371 of and claims priority to International Application No. PCT/EP2016/064117, filed 20 Jun. 2016, which claims the priority benefit of DE Application No. 10 2015 110 087.8, filed 23 Jun. 2015.

### FIELD OF THE INVENTION

The invention pertains to a device for transporting a strip-shaped substrate through a reactor, wherein the substrate is held by transport elements that can be displaced in a transport direction by a drive unit.

### BACKGROUND

DE 32 14 999 A1 describes a device for continuously transporting a workpiece through a furnace, wherein the workpiece is horizontally transported in alternating cycles by one of two walking beams.

DE 10 2013 108 056 A1 describes a substrate conveyor system for horizontally conveying an endless substrate, wherein rolling units, which are guided along rails, engage on the edges of the substrate.

WO 2013/028496 A1 describes a conveyor device for an endless substrate, in which the edges of the substrate are clamped between two motion-driven conveyor belts.

The deposition of graphenes or carbon nanotubes or other carbon nanoparticles requires a process chamber, in which the substrate is heated to a process temperature that lies above 1000° C. One surface of a strip-shaped endless substrate is coated in the reactor, in the process chamber of which the deposition process takes place. The substrate is unwound from a first reel on one side of the reactor and once again wound up on a second reel on the other side of the reactor. The substrate may consist of a metal strip, the stability of which drops to such a degree at the process temperatures that auxiliary means are required for stabilizing the substrate during its transport through the process chamber of the reactor.

### SUMMARY OF THE INVENTION

The invention is based on the objective of disclosing a transport device for a strip-shaped substrate, which conveys the substrate through the reactor with a low mechanical load.

This objective is attained with the invention disclosed in the claims, wherein the dependent claims not only represent advantageous enhancements of the master claim, but also independent inventive solutions.

The above-defined objective is initially and essentially attained in that the transport means comprise first and second transport beams. According to the invention, the transport beams are moved in a reciprocating fashion. When at least a first transport beam is displaced in the transport direction, at least a second transport beam is simultaneously displaced back in the form of a reverse motion opposite to the transport direction. A control unit and actuating drives are provided and make it possible to displace the transport beams in such a way that only the at least one transport beam being displaced in the forward direction engages on the substrate whereas the transport beam being displaced in the reverse direction does not engage on the substrate. In a first variation, the transport beams may be motion-driven in such a way that the first transport beam moves in one direction while the second transport beam moves in the opposite direction. The transport beams may reverse their motion at the same time, wherein the transport beam, which respectively engages on the substrate, changes when the motion reversal takes place. In this case, the drive is realized incrementally similar to an indexing gear. However, it is also proposed that the control unit activates the driving and adjusting devices for displacing the transport beams in such a way that a change of the engagement on the substrate takes place during the motion of the substrate. In this case, the transfer of the transport function takes place prior to the time, at which the motion of the transport beams is reversed. For example, when the first transport beams are slowly displaced in the transport direction, the second transport beams, which do not engage on the substrate, are at the same time rapidly displaced back in the reverse direction. The second transport beams are accelerated to the transport speed shortly before the first transport beams reach their end position such that the first and the second transport beams are displaced with the same speed. The engagement on the substrate changes from the first transport beams to the second transport beams during this parallel motion of both transport beams. As the second transport beams transport the substrate onward with the transport speed, the first transport beams are simultaneously displaced back in the reverse direction with increased speed in order to be analogously accelerated to the transport speed when the second transport beams approach their end position and to subsequently once again take over the transport of the substrate in a phase, in which all transport beams are displaced in the transport direction with the transport speed. The transport beams preferably engage on both longitudinal edges of the substrate. However, the transport beams may also support the substrate, for example, in the center or at other locations. According to a first aspect of the invention, transport beams on the edges feature clamping flanks that may be formed by clamping surfaces. It is particularly proposed to provide upper and lower transport beams, which feature clamping flanks that face one another. These clamping flanks can be clamped against the edge of the substrate by moving the upper and lower transport beams toward one another. In this way, a non-positive connection between the substrate and the transport means is produced such that the transport means engaging on the substrate convey the substrate in the transport direction while the transport means that do not engage on the substrate, i.e. the transport beams that are spaced apart from the substrate, are displaced back opposite to the transport direction. However, it is also possible to provide transport means that only support the substrate from below. The substrate may also be supported between its edges. It is preferred to provide transport carriages that hold the transport beams. The transport carriages can be horizontally displaced relative to a stationary carrier. This is realized with horizontal drives that are activated by the control unit. The horizontal drives may be realized in the form of pinions that engage into a stationary rack of the carrier and are driven by a motor mounted on the transport carriage. However, it is also possible to rigidly connect the rack to the transport carriage and to assign the motor and the pinion to the carrier. Furthermore, hydraulic or pneumatic drives may also be provided. The transport carriages respectively carry out a reciprocating motion during the transport motion of the substrate. It is particularly proposed that two transport carriages are respectively arranged on each side of the reactor, i.e. on the side, on which the substrate enters the reactor, and on the other side, on which the substrate exits the reactor. It is proposed that the ends of the first and the second transport beams respectively are rigidly connected to an assigned transport carriage in the horizontal direction. In this case, the transport beams extend through the reactor and its process chamber such that each transport beam is connected to a transport carriage on the substrate inlet side and a transport carriage on the substrate outlet side. The transport beams preferably have different lengths such that, for example, the at least one first transport beam may be shorter than the at least one second transport beam. As the transport carriages arranged on one side of the reactor carry out a motion toward one another, the transport carriages arranged on the other side of the reactor carry out a motion away from one another. In this case, the substrate is unwound from a supply reel on the inlet side and wound up on a reel on the outlet side. The temperature within the reactor 20, i.e. in the approximate center of the transport beam, lies above 1000° C. The transport beams therefore have heat-resistant properties, particularly in this central region. They may consist of quartz, ceramic or of special steel. However, they may also be composed of multiple different materials. The temperature lies below 100° C., preferably below 50° C., on the two ends where the transport carriages are located. A temperature gradient is therefore formed in the longitudinal direction of the transport beams, i.e. in the substrate transport direction. It may furthermore be advantageous to arrange multiple transport beam arrangements behind one another in transport directions. In this context, it is even possible that two different transport beam arrangements or pairs of transport beam arrangements border on one another in the center of the process chamber such that one substrate transport device, which consists of at least two transport beams, conveys the substrate up to the center of the process chamber and a second substrate transport device, which likewise comprises at least two transport beams, conveys the substrate onward through the process chamber from the center thereof. It would furthermore be conceivable that the first and the second transport beams respectively have the same length.

A second aspect of the invention concerns a device for transporting a strip-shaped substrate through a reactor, wherein the substrate is held by transport elements that can be displaced in a transport direction by a drive unit, wherein the transport means comprise first transport beams and second transport beams that alternately engage on the substrate, and wherein the transport beams, which respectively engage on the substrate, are moved in the transport direction and the transport beams, which respectively do not engage on the substrate, are moved in a reverse direction opposite to the transport direction. Transport carriages for displacing the transport beams in the transport direction essentially are arranged in pairs upstream and downstream of the reactor referred to the transport direction.

### BRIEF DESCRIPTION OF THE DRAWINGS

The invention is described in greater detail below with reference to an exemplary embodiment. In the drawings:

FIG. 1 shows a schematic side view of a transport device, by means of which a strip-shaped flexible substrate 1 is unwound from a first reel 16, conveyed through the process chamber of a reactor 20 and wound up on a second reel 17, wherein this figure shows a motion phase, in which a first transport beam arrangement 13, 13′, 3, 4 carries out a reverse motion R and a second transport beam arrangement 14, 14′, 5, 6 is driven so as to carry out a forward motion V, and wherein the transport beams 5, 6 clamp the substrate 1 between two clamping surfaces 11, 12;

FIG. 2 shows a section along the line II-II, wherein components, which lie downstream of the transport carriage 14 of the second transport beam arrangement referred to the transport direction V, are omitted;

FIG. 3 shows a section along the line III-III in FIG. 1, wherein components, which lie downstream of the transport carriage 13 of the first transport beam arrangement referred to the transport direction V, are omitted;

FIG. 4 shows a representation according to FIG. 1, however, in a different operating position, in which the first transport beam arrangement 13, 3, 4 engages on the substrate 1 with clamping surfaces 9, 10 and is displaced in the forward direction V while the second transport beam arrangement 14, 5, 6 does not engage on the substrate 1 and is displaced back in the reverse direction R;

FIG. 5 shows a section along the line V-V in FIG. 4, wherein components arranged downstream of the transport carriage 14 referred to the transport direction V are also omitted in this figure;

FIG. 6 shows a section along the line VI-VI in FIG. 4, wherein elements of the device arranged downstream of the transport carriage 13 referred to the transport direction are likewise omitted in this figure;

FIG. 7 shows a representation similar to FIGS. 1 and 4 in a first motion reversal point of the first transport beam arrangement 13, 3, 4 and the second transport beam arrangement 14, 5, 6;

FIG. 8 shows a representation according to FIG. 7, however, in a second motion reversal point of the two transport beam arrangements;

FIG. 9 shows a path-time diagram for elucidating the motion and the changeover times w1 to w6 while the substrate 1 is driven so as to carry out a uniform motion; and

FIG. 10 shows a top view of a substrate transport device according to a second exemplary embodiment, which comprises two transport beam arrangements 3, 4, 13; 5, 6, 14.

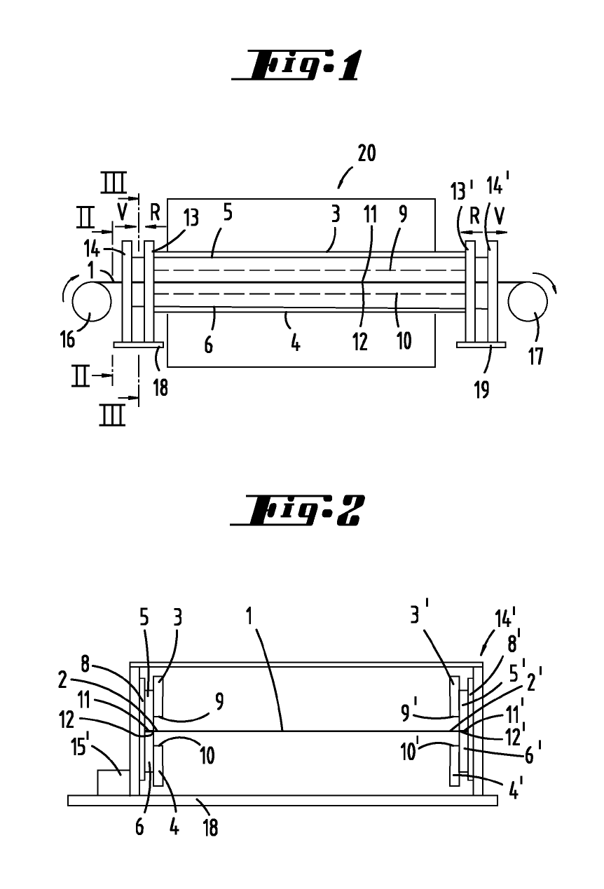

### DETAILED DESCRIPTION OF THE EMBODIMENTS

The figures show a transport device in combination with a CVD reactor 20 in the form of merely schematic representations. The reactor 20 serves for depositing carbon nanoparticles, graphenes, carbon nanotubes or the like as described in the prior art and in the relevant literature. Starting materials are introduced into a process chamber of the reactor 20, particularly in gaseous form. An endless substrate 1, particularly a metallic endless substrate, is conveyed through the process chamber of the reactor 20. The substrate and the process chamber of the reactor 20 are respectively heated to a temperature in excess of 1000° C. At this temperature, the nanoparticles are deposited on the surface of the substrate 1. The width of the substrate may amount to approximately 300 mm. Such a narrow substrate only has to be taken hold of on the edges that face away from one another. A support in the central region is not required in this case, but may optionally also be provided.

A first transport beam arrangement 13, 3, 4 and a second transport beam arrangement 14, 5, 6 are provided and alternately engage on the edge 2, 2′ of the substrate 1 by means of respective clamping surfaces 9, 9′, 10, 10′ and 11, 11′, 12, 12′ in order to convey the substrate 1 being unwound from a first reel 16 through the process chamber of the reactor 20, whereupon the substrate 1 is once again wound up on a second reel 17. The substrate 1 is in the process transported in a forward direction V.

The first transport beam arrangement comprises a first transport carriage 13 that features a gate-shaped frame, on which vertical drives 7, 7′ (see FIG. 3) are mounted. The vertical drives 7, 7′ are arranged near the edge of the substrate 1 being conveyed through the gate opening of the transport carriage 13. Upper transport beams 3, 3′ and lower transport beams 4, 4′, which are respectively arranged on the edge 2, 2′ of the substrate 1, can be displaced upward and downward with the aid of the vertical drives 7, 7′. The first transport beams 3, 3′, 4, 4′ form inner transport beams. They can be displaced from the spaced-apart position illustrated in FIG. 3 into the clamping position illustrated in FIG. 5. In this clamping position, the edge 2, 2′ of the substrate 1 respectively lies between the clamping surfaces 9, 9′; 10, 10′ of the upper transport beams 3, 3′ and the lower transport beams 4, 4′.

A transport carriage 13, 13′ is respectively located on the inlet side of the reactor 20, as well as on the outlet side of the reactor 20, and respectively holds one end of the first transport beams 3, 3′, 4, 4′. The two first transport carriages 13, 13′ can be horizontally displaced relative to a stationary carrier 18 by means of a horizontal drive 15. According to the invention, a reciprocating displacement is carried out.

A second transport beam arrangement 14, 5, 6 is also provided. This transport beam arrangement likewise comprises two transport carriages 14, 14′, wherein one transport carriage 14 is respectively arranged on the substrate inlet side of the reactor 20 and one transport carriage 14′ is arranged on the substrate outlet side of the reactor 20. Analogous to the first transport beam arrangement, the second transport beam arrangement also comprises a total of four transport beams 5, 5′, 6, 6′, wherein these transport beams form outer transport beams that can likewise engage on the edge 2, 2′ of the substrate. The second transport beams 5, 5′, 6, 6′, the ends of which are respectively mounted on a transport carriage 14, 14′, are longer than the first transport beams 3, 3′, 4, 4′. The transport carriages 14, 14′ feature a horizontal drive 15, 15′ for driving the second transport beam arrangement so as to carry out a horizontal reciprocating motion.

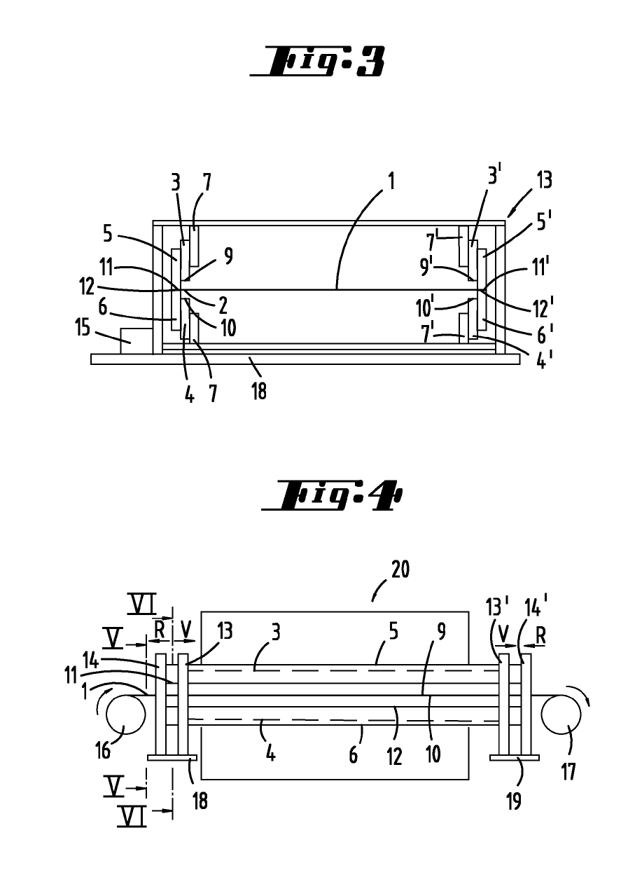

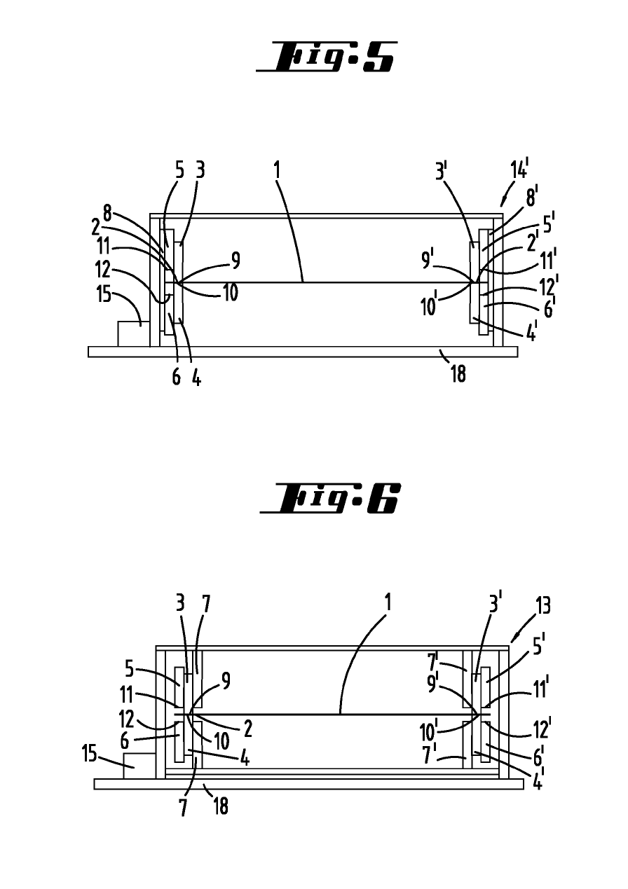

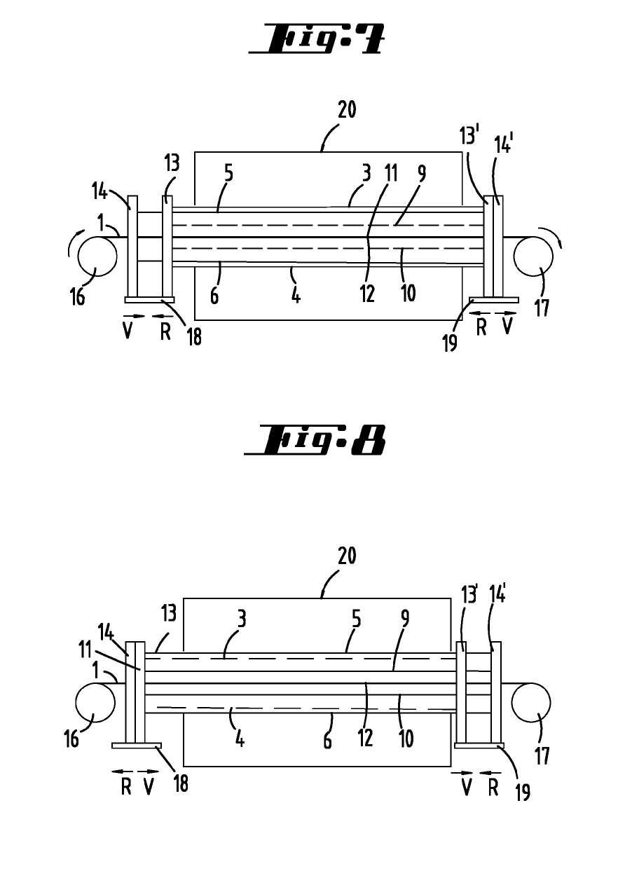

The gate-shaped second transport carriages 14, 14′ carry second vertical drives 8, by means of which the second transport beams 5, 5′, 6, 6′ can be displaced from the clamping position illustrated in FIG. 2 into the position illustrated in FIG. 5, in which they are spaced apart from the edge 2 of the substrate 1. For this purpose, upper transport beams 5, 5′ are displaced upward and lower transport beams 6, 6′ are displaced downward. In the process, an upper clamping surface 11, 11′ of an upper transport beam 5, 5′ respectively moves away from a lower clamping surface 12, 12′ of a lower transport beam 6, 6′.

The vertical drives 8, 8′, 7, 7′ may consist of rack-and-pinion drives, spindle drives or hydraulic or pneumatic piston-cylinder drives. The horizontal drives 15, 15′ may consist of gearings, in which, for example, a pinion engages into a rack. Torque-limited servomotors are used in the horizontal drive. The vertical motion may be carried out by means of a rotatable eccentric arm.

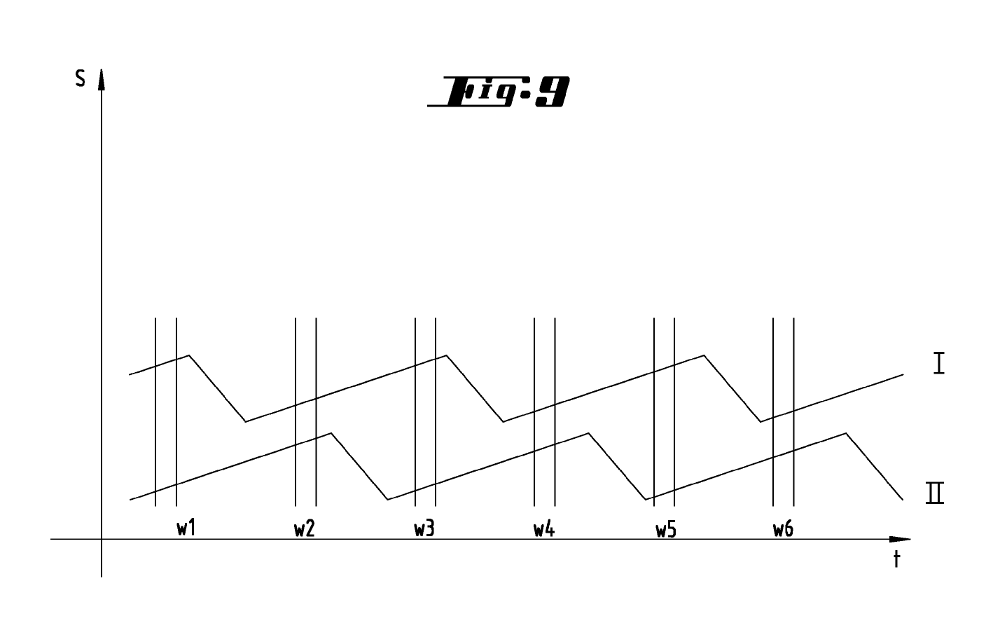

The device may be operated in an incremental mode. In this mode, the two clamping beam arrangements are respectively displaced in opposite directions, wherein the clamping beam arrangement moving in the forward direction V conveys the substrate 1. For this purpose, the corresponding clamping surfaces 10, 10′, 11, 11′, 12, 12′ clamp the edge 2, 2′ of the substrate 1 between one another. However, the transport beam arrangement being displaced in the reverse direction R has clamping surfaces 9, 12 that are spaced apart from the edge 2, 2′ of the substrate 1. In this case, the two transport beam arrangements are displaced between the motion reversal positions that are illustrated in FIGS. 7 and 8 and reached simultaneously.

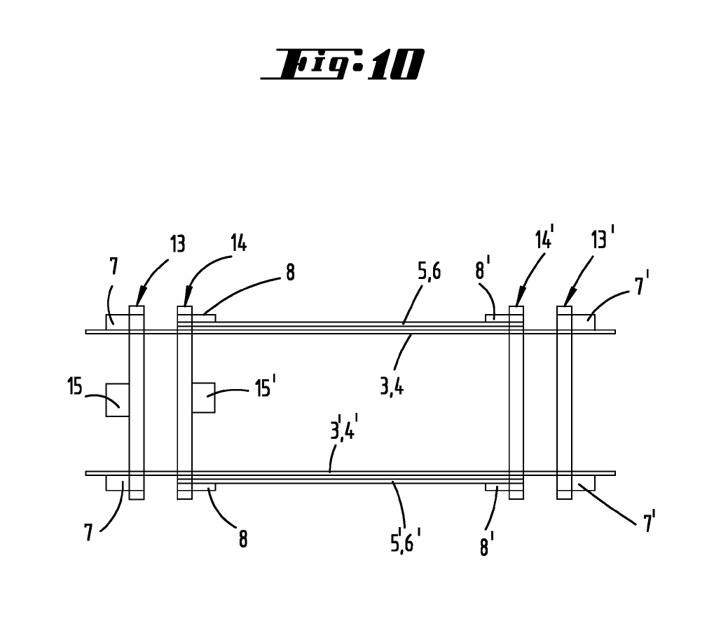

However, it is also possible to convey the substrate 1 with a uniform, continuous motion. The corresponding motion diagram is illustrated in FIG. 9. In this diagram, the moving distance S of the two transport beam arrangements I, II is plotted as a function of the time t.

The reference symbols w1 to w6 identify the time segments, in which the function of the respective clamping beam arrangement in the form of a substrate-conveying arrangement or reverse-displaced arrangement changes. During w1, the clamping of the substrate 1 by the clamping elements of the first transport beam arrangement 1 is released and the clamping elements of the second transport beam arrangement are moved into a clamping position such that the second transport beam arrangement takes over the transport of the substrate 1. The first transport beam arrangement is then rapidly displaced back in the reverse direction and takes over the transport of the substrate at w2. At w3, the transport once again changes from the first transport beam arrangement to the second transport beam arrangement. Analogous changes are identified with w4, w5 and w6. FIG. 9 elucidates that both transport beam arrangements I, II have the same speed at the time, at which the clamping changes w1 to w6 take place.

FIG. 10 shows a top view of a substrate conveyor device. The conveyor device comprises outer transport beams 5, 6 and 5′, 6′, which are respectively mounted on a transport carriage 14, 14′ with their longitudinal ends. Vertical drives 8, 8′ are arranged on the transport carriages 14, 14′ in order to vertically displace the transport beams 5, 5′, 6, 6′ in the above-described fashion. In this case, the transport carriages 14, 14′ also consist of gate-shaped objects.

The two inner transport beams 3, 4 and 3′, 4′ are longer than the outer transport beams 5, 6, 5′, 6′. They are respectively mounted on a transport carriage 13, 13′ with their longitudinal ends. The transport carriages 13, 13′ also consist of gate-shaped objects. During their respective motions, the transport carriages 13 can be displaced until they contact the transport carriages 14 and the transport carriages 13′ can be displaced until they contact the transport carriages 14′. The vertical drives 7, 7′ and 8, 8′ are therefore arranged on the vertical struts of the gate-shaped transport carriages 13, 13′, 14, 14′ on sides that face away from one another.

The preceding explanations serve for elucidating all inventions that are included in this application and respectively enhance the prior art independently with at least the following combinations of characteristics, namely:

A device, which is characterized in that the transport means comprise first transport beams 3, 3′, 4, 4′ and second transport beams 5, 5′, 6, 6′ that alternately engage on the substrate 1, wherein the transport beams, which respectively engage on the substrate 1, are moved in the transport direction V and the transport beams, which respectively do not engage on the substrate, are moved in a reverse direction R opposite to the transport direction V.

A device, which is characterized in that transport carriages 13, 13′, 14, 14′ are respectively arranged in pairs upstream and downstream of the reactor (20) referred to the transport direction V.

A device, which is characterized in that the transport carriages 13, 13′, 14, 14′ are arranged and connected to one another with transport beams 3, 3′ to 6, 6′ in such a way that the transport carriages 13′, 14′ arranged on one side of the reactor 20 move away from one another during a motion phase, in which the transport carriages 13, 14 arranged on the other side of the reactor 20 move toward one another, wherein the first transport beams 3, 3′, 4, 4′ are shorter than the second transport beams 5, 5′, 6, 6′.

A device, which is characterized in that the transport beams 3, 3′, 4, 4′, 5, 5′, 6, 6′ feature clamping flanks 9, 9′, 10, 10′, 11, 11′, 12, 12′, particularly for clamping the edge 2, 2′ of the substrate 1 between two clamping flanks.

A device, which is characterized in that the transport beams comprise lower transport beams 4, 4′, 6, 6′ and upper transport beams 3, 3′, 5, 5′, wherein the substrate 1 is held by the transport beams, which are respectively displaced in the transport direction V, due to its position between two clamping surfaces 9, 9′, 10, 10′, 11, 11′, 12, 12′ of an upper and a lower transport beam.

A device, which is characterized in that the transport beams 3, 3′, 4, 4′, 5, 5′, 6, 6′ can be moved from a position, in which they contact the substrate 1, into a position, in which they are spaced apart from the substrate 1, in a direction extending transverse to the surface normal of the substrate 1 by means of vertical drives 7, 7′, 8, 8′.

A device, which is characterized by horizontal drives 15, 15′ for horizontally displacing the transport carriages 13, 13′, 14, 14′ and vertical drives 7, 7′, 8, 8′ for displacing the transport beams 3, 3′, 4, 4′, 5, 5′, 6, 6′ between a position, in which they contact the substrate 1, and a position, in which they are spaced apart from the substrate 1, wherein the drives 15, 15′; 7, 7′, 8, 8′ are controlled in such a way that the displacement of the transport beams takes place in the motion reversal points of the transport carriages or during a motion of all transport carriages 13, 13′, 14, 14′ in the transport direction V.

A device, which is characterized in that the reactor 20 is a CVD reactor.

A device, which is characterized in that carbon nanoparticles, graphenes or carbon nanotubes are deposited on the substrate 1 with the reactor 20, particularly at a temperature >1000° C.

All disclosed characteristics are essential to the invention (individually, but also in combination with one another). The disclosure content of the associated/attached priority documents (copy of the priority application) is hereby fully incorporated into the disclosure of this application, namely also for the purpose of integrating characteristics of these documents into claims of the present application. The characteristic features of the dependent claims characterize independent inventive enhancements of the prior art, particularly for submitting divisional applications on the basis of these claims.

### REFERENCE LIST

1 Substrate
2 Edge
2′ Edge
3 Transport beam
3′ Transport beam
4 Transport beam
4′ Transport beam
5 Transport beam
5′ Transport beam
6 Transport beam
6′ Transport beam
7 Vertical drive
7′ Vertical drive
8 Vertical drive
8′ Vertical drive
9 Clamping surface
9′ Clamping surface
10 Clamping surface
10′ Clamping surface
11 Clamping surface
11′ Clamping surface
12 Clamping surface
12′ Clamping surface
13 Transport carriage
13′ Transport carriage
14 Transport carriage
14′ Transport carriage
15 Horizontal drive
15′ Horizontal drive
16 Reel
17 Reel
18 Carrier
19 Carrier
20 Reactor
R Reverse direction
V Transport direction

1. A device for transporting a strip-shaped substrate (1) through a reactor (20), the device comprising:
a horizontal drive (15, 15′) for displacing the substrate (1) in a transport direction (V);
transport elements (3, 3′, 4, 4′, 5, 5′, 6, 6′) for holding the substrate (1),
wherein the transport elements comprise first transport beams (3, 3′, 4, 4′) and second transport beams (5, 5′, 6, 6′) that alternately engage the substrate (1),
wherein when the first transport beams engage the substrate (1) and move in the transport direction (V), the second transport beams are configured to not engage the substrate and move in a reverse direction (R) opposite to the transport direction (V), and
wherein the first transport beams and second transport beams (3, 3′, 4, 4′, 5, 5′, 6, 6′) feature clamping surfaces (9, 9′, 10, 10′, 11, 11′, 12, 12′) for clamping an edge (2, 2′) of the substrate (1) between two of the clamping surfaces.

2. The device of claim 1, further comprising a first pair of transport carriages (13, 14) arranged upstream of the reactor (20) and a second pair of transport carriages (13′, 14′) arranged downstream of the reactor (20) with respect to the transport direction (V).

3. The device of claim 2, wherein the first and second pairs of transport carriages (13, 13′, 14, 14′) are arranged and connected to one another by the first and second transport beams (3, 3′, 4, 4′, 5, 5′, 6, 6′) in such a way that the second pair of transport carriages (13′, 14′) arranged on one side of the reactor (20) move away from one another during a motion phase, in which the first pair of transport carriages (13, 14) arranged on the other side of the reactor (20) move toward one another, and wherein the first transport beams (3, 3′, 4, 4′) are shorter than the second transport beams (5, 5′, 6, 6′).

4. The device of claim 1, wherein the first and second transport beams comprise lower transport beams (4, 4′, 6, 6′) and upper transport beams (3, 3′, 5, 5′), which are respectively displaced in the transport direction (V), and wherein the substrate (1) is held by clamping surfaces (10, 10′, 12, 12′) of the lower transport beams and clamping surfaces (9, 9′, 11, 11′) of the upper transport beams.

5. The device of claim 1, wherein each of the first and second transport beams (3, 3′, 4, 4′, 5, 5′, 6, 6′) are moveable from a first position, in which it contacts the substrate (1), into a second position, in which it is spaced apart from the substrate (1), in a direction extending transverse to a surface of the substrate (1) by means of vertical drives (7, 7′, 8, 8′).

6. The device of claim 2, further comprising vertical drives (7, 7′, 8, 8′), wherein the horizontal drives (15, 15′) are configured to horizontally displace the first and second pairs of transport carriages (13, 13′, 14, 14′) and the vertical drives (7, 7′, 8, 8′) are configured to vertically displace the first and second transport beams (3, 3′, 4, 4′, 5, 5′, 6, 6′) between a first position, in which they contact the substrate (1), and a second position, in which they are spaced apart from the substrate (1), wherein the horizontal and vertical drives (15, 15′; 7, 7′, 8, 8′) are controlled in such a way that the vertical displacement of the first and second transport beams takes place in motion reversal points of the first and second pairs of the transport carriages or during a motion of all transport carriages (13, 13′, 14, 14′) in the transport direction (V).

7. The device of claim 1, wherein the reactor (20) is a chemical vapor deposition (CVD) reactor.

8. The device of claim 1, wherein the reactor (20) is configured to deposit carbon nanoparticles, graphenes or carbon nanotubes on the substrate (1) at a temperature greater than 1000° C.

9. (canceled)
